(19) United States
(12) Patent Application Publication
(10) Pub. No.: US 2023/0411309 A1
(43) Pub. Date: Dec. 21, 2023

(54) RF SUBSTRATE COMPRISING DEPLETION REGIONS INDUCED BY FIELD EFFECT

(71) Applicants: COMMISSARIAT A L'ENERGIE ATOMIQUE ET AUX ENERGIES ALTERNATIVES, Paris (FR); UNIVERSITE CATHOLIQUE DE LOUVAIN, Louvain-la-Neuve (BE)

(72) Inventors: Louis HUTIN, Grenoble Cedex 09 (FR); Maxime MOULIN, Grenoble Cedex 09 (FR); Thibaud FACHE, Grenoble Cedex 09 (FR); Christophe PLANTIER, Grenoble Cedex 09 (FR); Jean-Pierre RASKIN, Louvain-la-Neuve (BE); Martin RACK, Louvain-la-Neuve (BE)

(73) Assignees: COMMISSARIAT A L'ENERGIE ATOMIQUE ET AUX ENERGIES ALTERNATIVES, Paris (FR); UNIVERSITE CATHOLIQUE DE LOUVAIN, Louvain-la-Neuve (BE)

(21) Appl. No.: 18/337,269

(22) Filed: Jun. 19, 2023

(30) Foreign Application Priority Data
Jun. 21, 2022 (FR) 22 06090

(51) Int. Cl. H01L 23/58

(52) U.S. Cl. CPC H01L 23/58; H01L 27/13

(57) ABSTRACT

A structure for an RF device provided with a semiconductor region coated with a heterogeneous dielectric region, the heterogeneous dielectric region including, in at least one first direction parallel to a main plane of the substrate, an alternation of first areas made of a first dielectric material with positive fixed charges and of second dielectric areas made of a second dielectric material with negative fixed charge in order to create an alternation of polarity allowing preventing the formation of a parasitic conduction layer in the semiconductor region.

### TECHNICAL FIELD AND PRIOR ART

This application relates to the field of microelectronics and in particular that of devices intended for radio frequency (RF) applications.

In the RF microelectronic devices, a parasitic conduction layer commonly called “PSC” (for “Parasitic Surface Conduction”) is likely to be created in a semiconductor portion arranged in an upper part of a substrate.

A known improvement in substrates for the RF applications and in particular semiconductor-on-insulator type substrates consists in forming under and against an insulating layer of the substrate which is commonly called “BOX”, a trapping layer also called “trap rich”. Such a layer is typically formed of a semiconductor material rich in crystalline defects and which allows trapping charges.

The trapping layer may in particular be a polysilicon layer produced at the interface with the insulating layer. The free carriers attracted to the interface are trapped therein, and therefore do not participate in the parasitic surface conduction. With such a layer, the parasitic conduction near the insulating layer is limited, and in this way the performance of the radiofrequency circuits is improved in terms of radiofrequency isolation, reduction of insertion losses and signal integrity.

Such a trapping layer is generally obtained via a manufacturing method applied over the entire extent of the substrate. The document WO 2 005 031 842 A2 gives an example of such a method.

A second manner to limit the circulation of the stray currents is proposed in the document “Low-Loss Si-Substrates Enhanced Using Buried PN Junctions for RF Applications” by Rack et al., IEEE Electron Device Letters, 2019. In this document, an alternation of N-type doped strips and P-type doped strips is made in order to avoid the creation of a continuous PSC type layer.

This solution requires the implementation of implantation steps and in particular the use of two dedicated implantation masks, which should preferably be correctly aligned.

Another solution to improve the integrity of radio frequency signals in high resistivity semiconductor substrates is to implement a specific biasing by field effect using dedicated control conductor tracks. Such tracks are typically made at the same level as the transistor gate(s) or else in the first metal interconnection level commonly called “metal 1” (or M1). The document of Rack et al. “Field-Effect Passivation of Lossy Interfaces in High-Resistivity RF Silicon Substrates,” 2021 Joint International EUROSOI Workshop and International Conference on Ultimate Integration on Silicon (EuroSOl-ULIS), 2021 presents such a method. Depletion areas are created remotely, thanks to an electrostatic potential applied to these conductive control tracks. This solution requires the insertion of additional bias conductor tracks and the use of a power amplifier to route an adequate bias level onto these tracks.

There arises the problem of finding a new structure which allows preventing or limiting the formation of a PSC layer and this without necessarily having to make use of a specific biasing electrode and/or having to carry out additional dopant implantations.

### DISCLOSURE OF THE INVENTION

According to one embodiment, provision is made for a structure for an RF device provided with a substrate which is provided with a semiconductor region, the semiconductor region being coated with at least one heterogeneous dielectric region, said heterogeneous dielectric region including, in at least one first given direction parallel to a main plane of the substrate, an alternation of first areas made of a first dielectric material with positive fixed charges and of second dielectric areas made of a second dielectric material with negative fixed charges.

An alternation of dielectric materials containing fixed charges, whose sign also alternates, is thus provided opposite to the semiconductor region.

An alternation of polarity is thus created by field effect which acts within the semiconductor region of the substrate, this without resorting to a doping or to a use of additional specific gates or control tracks.

Advantageously, said first and second dielectric areas can be distributed periodically in said first direction.

The alternation of dielectric materials with positive fixed charges and with negative fixed charges can be carried out in several directions parallel to the main plane of the substrate.

Thus, advantageously, in at least one second direction making a non-zero angle with the first direction and parallel to a main plane of the insulating layer, the dielectric region may include an alternation of areas based on the first dielectric material and dielectric areas based on the second dielectric material.

According to one possibility of implementation, the dielectric areas based on the first dielectric material and based on the second dielectric material can form a spiral or checkerboard arrangement.

Advantageously, the first dielectric material with positive fixed charges is selected from the following materials: silicon oxide, silicon nitride, silicon oxycarbide.

Advantageously, the second dielectric material with negative fixed charges is selected from the following materials: alumina, hafnium oxide.

The substrate on which the structure is formed can be
a bulk substrate or,
a semiconductor-on-insulator type substrate, said semiconductor region being a surface semiconductor layer or a region of a surface semiconductor layer disposed on an insulating layer of the substrate, said insulating layer being arranged on a semiconductor support layer, or
a hybrid substrate, said semiconductor region being a semiconductor island arranged on a first region of a semiconductor support layer of the hybrid substrate, the semiconductor support layer including a second region on which an insulating layer itself coated with a surface semiconductor layer are disposed.

According to one possibility of implementation for which the substrate is of the semiconductor-on-insulator type, the semiconductor support layer may include a charge trapping region, in particular a region rich in crystalline defects, such as a polysilicon layer.

Advantageously, the heterogeneous dielectric region is arranged on and in contact with said semiconductor region.

According to another aspect, the present application relates to a microelectronic device comprising:
a structure as previously defined,
one or more electronic components, in particular one or more transistors at least partially formed in a semiconductor region of said substrate
at least one RF component such as an antenna or an inductance, said RF component being arranged opposite to said heterogeneous dielectric region.

### BRIEF DESCRIPTION OF DRAWINGS

The present invention will be better understood based on the following description and the appended drawings in which:

FIG. 1 is used to illustrate an arrangement, to allow limiting or preventing a parasitic conduction phenomenon in a semiconductor layer of an RF device, by means of a heterogeneous dielectric region formed of areas of dielectric material with positive fixed charges and areas of dielectric material with negative fixed charges which are alternately distributed.

FIG. 2 is used to illustrate the performance of a structure of said arrangement to allow limiting or preventing the parasitic conduction.

FIG. 3 is used to illustrate an exemplary embodiment in which the heterogeneous dielectric region is formed on a bulk substrate.

FIG. 4 is used to illustrate an exemplary embodiment in which the heterogeneous dielectric region is produced in an FD-SOI type technology with hybrid areas.

FIG. 5 is used to illustrate an exemplary embodiment in which the heterogeneous dielectric region is formed on a semiconductor-on-insulator type substrate.

FIG. 6 is used to illustrate an exemplary embodiment in which the heterogeneous dielectric region is associated with a charge trapping layer.

FIG. 7 is used to illustrate a particular exemplary embodiment in which the heterogeneous dielectric region is formed on a semiconductor island arranged on a region of a substrate also including another semiconductor-on-insulator type region.

FIG. 8 is used to illustrate a first variant of the heterogeneous dielectric region.

FIG. 9 is used to illustrate a second variant of the heterogeneous dielectric region.

FIG. 10 is used to illustrate a third variant of the heterogeneous dielectric region.

FIG. 11 is used to illustrate a fourth variant of the heterogeneous dielectric region.

FIG. 12 is used to illustrate a fifth variant of the heterogeneous dielectric region.

### DETAILED DISCLOSURE OF PARTICULAR EMBODIMENTS

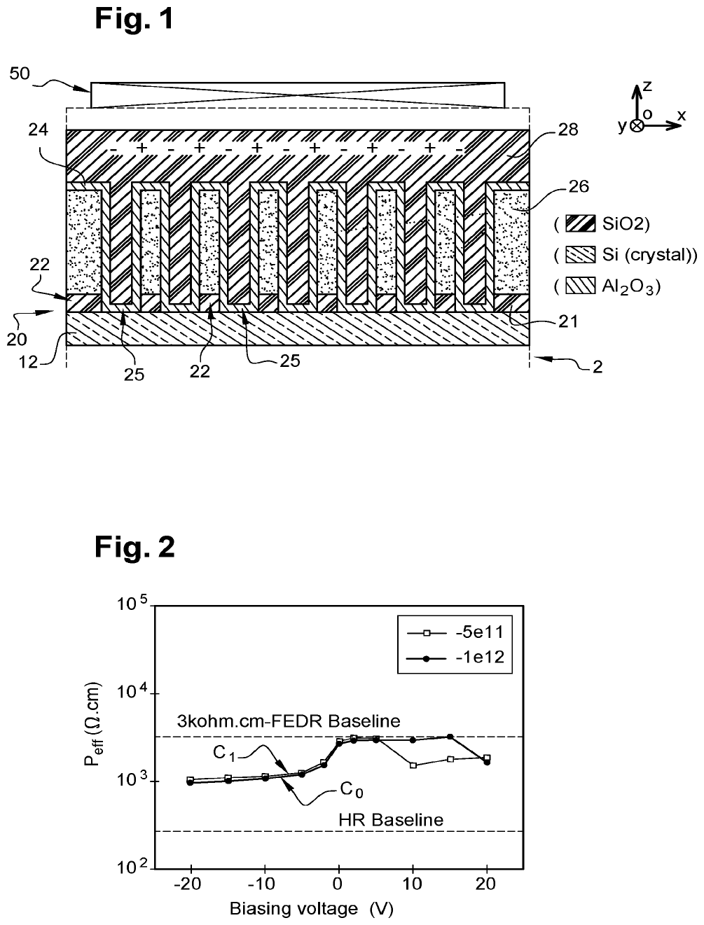

Reference is now made to FIG. 1 giving an example of a structure for an RF device including a heterogeneous dielectric region 20 in which an alternation of polarity is created.

The targeted RF signals are typically those having an electromagnetic wave frequency located between 10 kHz and 100 GHz, advantageously between 1 MHz and 100 GHz and in particular between 1 MHz and 50 GHz.

The structure applies in particular to space communications and telecommunications devices, for example to the devices operating according to the technology called “5G” technology, which designates the fifth generation of the standards for mobile telephony.

The heterogeneous dielectric region 20 allows avoiding parasitic conduction in a semiconductor layer 12. This semiconductor layer 12 is here an upper surface layer of a semiconductor substrate 2, for example a bulk substrate. The bulk substrate, for example made of silicon, may in particular be a substrate of high resistivity HR which is typically greater than 100 Ω·cm, and advantageously greater than 1 Ω·cm.

The heterogeneous dielectric region 20 is formed, in at least one first direction parallel to a main plane (i.e. a plane passing through the substrate 2 and which is parallel to the plane [O; x; y] of the reference frame [O; x; y; z] in FIG. 1), of an alternation of first dielectric areas based on a first dielectric material 22 and of second dielectric areas based on a second dielectric material 25. The first dielectric material 22 and the second dielectric material 25 are respectively a dielectric material with positive fixed charges and a dielectric material with negative fixed charges. The term “dielectric material with positive fixed charges” means here a material likely to include positive fixed charges without an external bias being necessary. Similarly, the term “dielectric material with negative fixed charges” means here a material likely to include negative fixed charges without an external bias being necessary. In the illustrated exemplary embodiment, the dielectric areas of dielectric material 22 with positive fixed charges and the dielectric areas of dielectric material 25 with negative fixed charges are in contact with each other.

The alternating distribution of dielectric areas based on a first dielectric material 22 and of second dielectric areas based on a second dielectric material 25 can be carried out in several directions parallel to the main plane of the substrate, for example so as to form a checkerboard or spiral pattern.

The dielectric material 22 with positive fixed charges is typically a material used in method steps commonly called “back-end of line” (BEOL), in other words a set of steps for manufacturing a circuit ranging from a first metallisation level to the circuit passivation method. The dielectric material 22 can advantageously be selected from the following materials: silicon oxide, in particular SiO₂, silicon nitride, silicon oxycarbide.

The second dielectric material 25, with negative fixed charges, can be, in turn, a material which is usually used to form certain gate dielectrics. The dielectric material can be selected from the following materials: alumina, in particular Al₂O₃ and hafnium oxide, in particular HfO₂.

A particular exemplary embodiment provides a heterogeneous dielectric region 20 composed of an alternation of SiO₂ areas and Al₂O₃ areas.

The dielectric areas with negative fixed charges and the dielectric areas with positive fixed charges are preferably distributed periodically, according to a given pitch which can be comprised between several nanometres and several micrometres, typically between 100 nm and 10 μm, for example in the micrometre range.

By this alternation of materials 22, 25, an alternation of polarity of charges is created in order to block the circulation of a parasitic current in the semiconductor layer 12. The blocking of parasitic conduction is carried out here without necessarily resorting to a specific doping or having to introduce additional specific bias electrodes.

In the heterogeneous dielectric region 20, the value of the positive and negative fixed charge densities in absolute value is typically comprised between 10¹⁰ charges/cm² and 10¹³ charges/cm².

In the particular embodiment illustrated in FIG. 1, the heterogeneous dielectric region 20 formed of the alternation of dielectric areas 22, 25 is arranged directly in contact with the upper semiconductor layer 12 of the substrate 2.

It is alternatively possible to provide the dielectric region 20 at a distance from the semiconductor layer 12, preferably a close distance, that is to say typically less than 500 nm while being able to maintain the current blocking effect. The maximum distance between the dielectric areas with positive and negative fixed charges and the semiconductor substrate advantageously depends on the amount of fixed charges in the different dielectric areas. The more significant this amount of fixed charges in these dielectrics, the more they can be disposed at a significant distance from the semiconductor substrate. A capacity is retained to modify the concentration of mobile charges in the semiconductor by field effect, and thus, to force electron-rich areas under the dielectric areas with positive fixed charges and to force hole-rich areas under the dielectric areas with negative charges.

The current blocking produced via this dielectric region 20 formed of an alternation of different dielectrics 22, 25 can be obtained here without a portion of the semiconductor layer 12 or of the substrate 2, located opposite to this alternation, itself including an alternation of doped areas of P and N opposite conduction types.

The repetition and the distribution pitch of the dielectric areas 22, 25 allows providing an RF component or RF conductive circuit or conductive element for an opposite RF circuit (one or the other of these elements being represented schematically by a block referenced 50 in FIG. 1) without necessarily having to carry out an accurate alignment of this component or of this circuit or of this conductive element relative to the dielectric region 20.

The heterogeneous dielectric region 20 can extend “full plate”, that is to say over the entire surface of the substrate 2.

Alternatively, the dielectric region 20 can advantageously be located outside areas where transistors are formed and preferably only on one or more areas arranged opposite to RF component(s) or circuit(s) or conductive element(s) for RF circuit. For example, when it is located opposite a coplanar waveguide or an inductor, the heterogeneous dielectric region 20 can typically extend over a distance of several tens of micrometres.

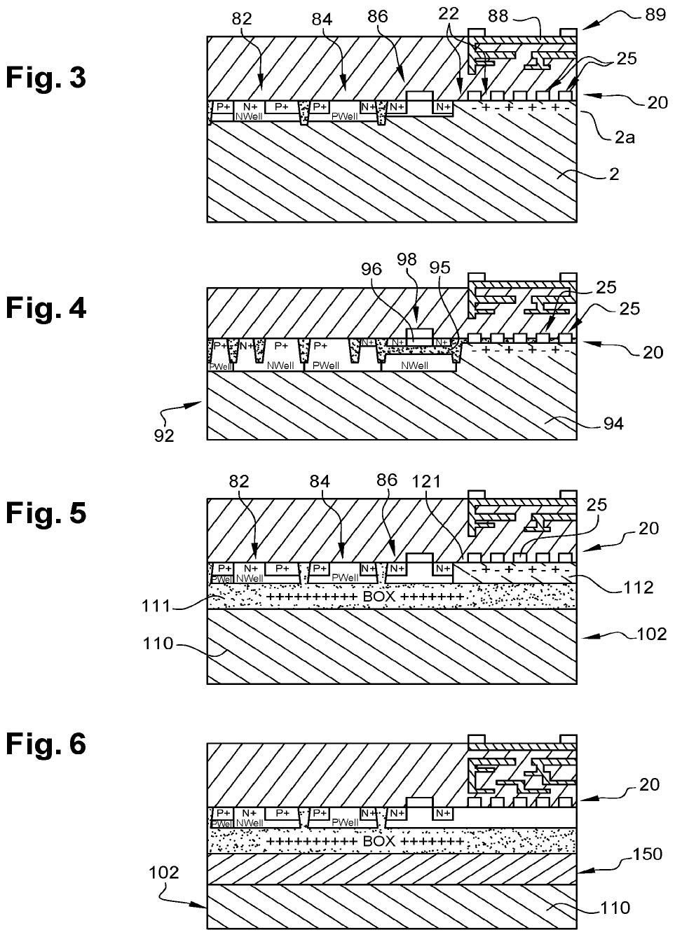

A particular exemplary embodiment of this variant illustrated in FIG. 3 provides for arranging the heterogeneous dielectric region 20 on a semiconductor region 2a of the bulk substrate 2 which is located on the periphery of parts in which bipolar transistors 82, diodes 84, and MOS transistors 86 are formed. The dielectric region 20 with dielectrics 22, 25 of opposite polarities is located opposite to a stack of insulating layers on which conductive tracks 89 are formed, for example made of Al, of an RF component and in which interconnection elements 88, for example made of Cu, are arranged.

In a simulation performed using a tool of the TCAD (for “Technology Computer Aided Design”) type for a SiO₂ dielectric 22 with positive charges and with a thickness of 1 μm, an Al₂O₃ dielectric 25 with negative charges and with a thickness of 20 nm, a distribution pitch of the dielectric areas of 1 μm, provision is made for negative fixed charges imposed for Al₂O₃ according to a density comprised between 5e11/cm² and 1e12/cm² and positive fixed charges imposed for SiO₂ in the range of 1e11/cm².

In FIG. 2, the curves Co and Ci are used to illustrate performance in terms of effective resistivity of a structure as implemented according to the invention, respectively for a concentration of negative fixed charges respectively in the range of −1e¹² and in the range of −5^{e}11, this relative to a conventional arrangement (“HR-Base line”) which does not include alternating dielectric regions respectively with positive fixed charges and with negative fixed charges.

According to another possibility of implementation, the heterogeneous dielectric region 20 formed of the alternation of dielectric areas 22, 25 can also be produced on a substrate of the semiconductor-on-insulator type, in particular an SOI (“Silicon On Insulator”) substrate including a semiconductor support layer coated with an insulating layer typically called “BOX”, itself coated with a surface semiconductor layer.

Thus, such a structure can be adapted to the production of circuits in technologies such as FD-SOI for (“Fully Depleted Silicon On Insulator” or fully depleted SOI) or PD-SOI for (“Partially Depleted Silicon On Insulator” or partially depleted SOI).

A particular embodiment of a device which can be produced using FD-SOI technology is given in FIG. 4. The dielectric region 20 formed of the dielectric areas with positive fixed charges and of dielectric areas with negative fixed charges is located and here juxtaposed to an area in which one or more transistors 98 are formed on an insulating layer typically a silicon oxide layer, thick enough, for example between 10 and 200 nm, to prevent an electrostatic coupling into a semiconductor support layer 94 of a substrate 92 and a surface semiconductor layer 96 in which the transistor 98 is formed.

Another particular embodiment in PD-SOI type technology is given in FIG. 5. The heterogeneous dielectric region 20 formed of the zones of dielectric materials 22, 25, is this time arranged on the surface semiconductor layer 112 of a semiconductor-on-insulator substrate 102 in which components, in particular bipolar transistors 82, diodes 84, and MOS transistors 86 are formed. The substrate 102, for example of the SOI type, includes a semiconductor support layer 110, for example made of silicon, an insulating layer 111, for example made of silicon oxide, located between the semiconductor support layer 110 and the surface semiconductor layer 112, for example made of silicon.

According to another variant, in order to allow limiting or avoiding the parasitic surface conduction, it is possible to provide, in combination with the dielectric region 20, a layer 150 for trapping charges in the support layer 110 of the substrate 102. Thus in the In the exemplary embodiment illustrated in FIG. 6, a charge trapping layer, for example made of polysilicon, extends opposite to the dielectric region 20 with dielectric materials of opposite polarity.

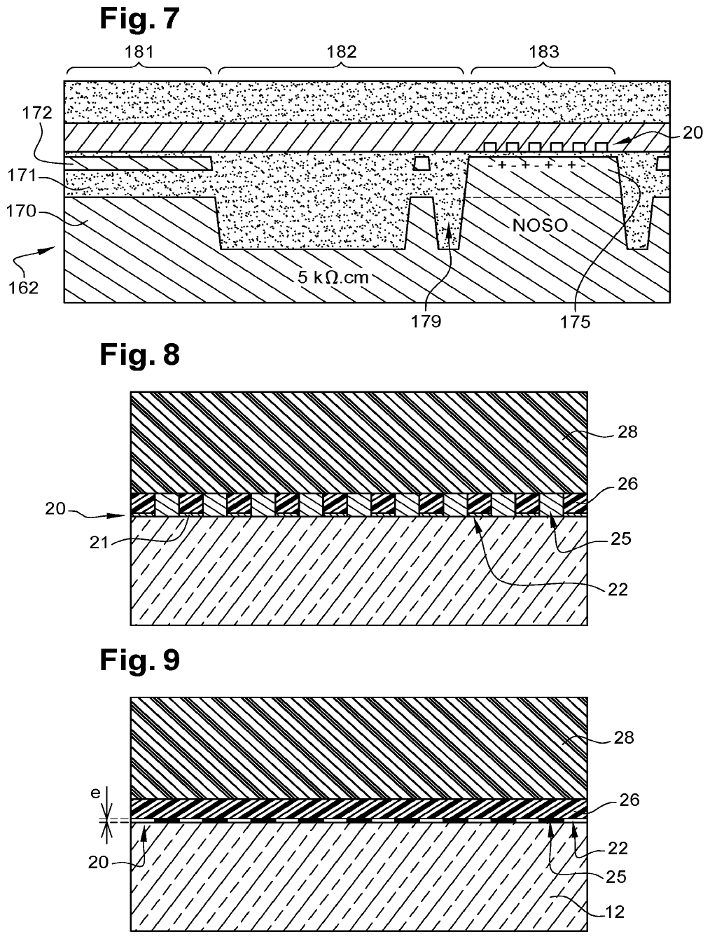

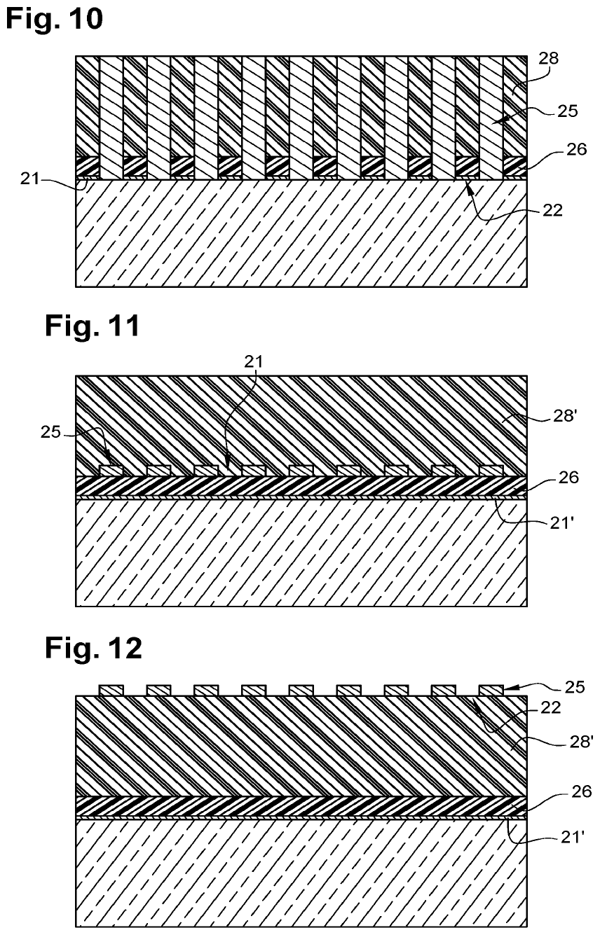

Another exemplary embodiment given in FIG. 7 provides for forming the dielectric region 20 on a semiconductor island 175 of a hybrid substrate 162.

This substrate 162 is here provided with at least a first region 181 of the semiconductor-on-insulator type including a semiconductor support layer 170 coated with an insulating layer 171 of BOX itself coated with a surface semiconductor layer 172, while the semiconductor island 175 is located in another region 183 in which the surface semiconductor layer 172 is not presented and/or has been removed. The semiconductor island 175 is typically made of a semiconductor material of high resistivity, or at least higher than that of the surface semiconductor layer. For example, the island can be provided with a resistivity in the range of at least one hundred times the resistivity of the surface semiconductor layer.

Such another region 183 called “NOSO” (for “No SOI”) is here separated from the first region 181 in which transistor type components are provided, by means of a separation region 182 in which insulating trenches 179 are provided.

A method for producing a heterogeneous dielectric region 20 as previously described consists in first depositing a first layer 21 based on the dielectric material 22, for example SiO₂, according to a thickness which can be for example comprised between 1 and 30 nm, and advantageously between 5 nm and 25 nm and for example in the range of 20 nm.

Then, another insulating layer 26 is formed, which may be a contact etch stop layer (CESL), for example made of silicon nitride. Such a layer 26 can have a thickness in the range of ten nanometres, for example comprised between 5 and 40 nm and typically in the range of 30 nm.

A plurality of openings are then made through the etch stop layer 26, for example by etching through a masking formed by photolithography. A deposition, in particular of the conformal type, of a layer 24 based on the dielectric material 25 with negative fixed charges is then carried out. The layer 24, for example 20 nm thick, is here deposited so as to line the bottom and the lateral walls of the openings. This deposition can be performed such that a central part of the openings is not filled by the dielectric material 25.

Several implementation possibilities can be considered to carry out the etching. According to a first possibility, this etching is stopped on the oxide layer 22 underlying the other CESL type insulating layer 26. In this case, it is then this CESL insulating layer 26 which acts as the positively charged layer. In another case where the layer 22 is etched and the silicon is stopped, it is the oxide layer 22 which acts as a positively charged layer.

A filling of the openings is then performed by means of an insulating layer 28. This layer 28 can be a pre-metal dielectric layer (PMD) for example based on SiO₂.

According to a variant illustrated in FIG. 8, the openings formed through the stack of the layer 21 based on dielectric material with positive fixed charges and of the contact etch stop layer 26, can be entirely filled by the dielectric material 25 with negative fixed charges. The dielectric material 25 with negative fixed charges is then removed in excess protruding above the openings by carrying out a CMP planarization step. Then, the PMD type insulating layer 28 can subsequently be formed.

According to another variant, provision may be made to form the areas of dielectric material 25 with negative fixed charges after deposition of the contact etch stop layer 26 (CESL) and of the insulating layer 28. The openings made through the layer 21 of dielectric material with positive fixed charges are then then subsequently practiced through a stack comprising the layer 21 based on dielectric material with positive fixed charges, the contact etch stop layer 26, the layer of insulating material 28. These openings are then filled as in FIG. 5 to form the areas of dielectric material 25 with negative fixed charges.

As previously indicated, and as illustrated in FIG. 11, the areas of dielectric material 25 with negative fixed charges and the areas of dielectric material 22 with positive fixed charges can be arranged at a distance from the semiconductor layer 12. The areas of dielectric material with negative fixed charges and the areas of dielectric material with negative fixed charges are then typically produced after the etch stop layer 26.

Thus, it is first possible to form an insulating layer 21′, for example made of TeOS. Then, the etch stop layer 26 is deposited, for example made of nitride.

Then, the dielectric areas based on dielectric material with negative fixed charges and dielectric areas based on dielectric material with positive fixed charges are formed.

The dielectric areas based on dielectric material 25 with negative fixed charges can be produced by deposition in which patterns are produced by photolithography. An Al₂O₃ layer with a thickness which can be for example in the range of nm can be formed for this.

The dielectric areas based on dielectric material with positive fixed charges can then be formed by depositing another insulating layer 28′, for example a PMD type layer made of SiO₂, filling in the spaces between the patterns of dielectric material with fixed negative charges and covering these patterns. This other insulating layer 28′ is produced for example by PECVD.

Such a variant allows limiting the number of etched layers and in particular having to etch layers of different materials.

According to another variant illustrated in FIG. 12, the dielectric areas based on dielectric material 25 with negative fixed charges are formed after the dielectric areas based on dielectric material 22 with fixed negative charges.

More generally, the order of the steps for producing the dielectric areas based on dielectric material 25 with negative fixed charges and the dielectric areas based on dielectric material 22 with fixed negative charges can be reversed.

1. A microelectronic device comprising:
a structure for an RF device provided with a substrate, the substrate being provided with a semiconductor region coated with at least one heterogeneous dielectric region, said heterogeneous dielectric region including, in at least one first given direction dl parallel to a main plane of the substrate, an alternation of first areas made of a first dielectric material with positive fixed charges and of second dielectric areas made of a second dielectric material with negative fixed charges.
one or more electronic components, in particular one or more transistors at least partially formed in a semiconductor region of said substrate,
at least one RF component such as an antenna or an inductance or a waveguide, said RF component being arranged opposite to said heterogeneous dielectric region.

2. The device according to claim 1, said first and second dielectric areas being distributed periodically in said first direction.

3. The device according to claim 1, wherein said dielectric region includes, in at least one second direction making a non-zero angle with the first direction and parallel to a main plane of the insulating layer, an alternation of areas based on the first dielectric material and dielectric areas based on the second dielectric material.

4. The device according to claim 1, wherein the first dielectric material with positive fixed charges is selected from the following materials: silicon oxide, silicon nitride, silicon oxycarbide.

5. The device according to claim 1, wherein the second dielectric material with negative fixed charges is selected from the following materials: alumina, hafnium oxide.

6. The device according to claim 1, wherein said substrate is:
a semiconductor bulk substrate or,
a semiconductor-on-insulator type substrate, said semiconductor region being a surface semiconductor layer disposed on an insulating layer of the substrate, said insulating layer being arranged on a semiconductor support layer of the substrate, or
a hybrid substrate, said semiconductor region being a semiconductor island arranged on a first region of a semiconductor support layer of the hybrid substrate, the semiconductor support layer including a second region on which an insulating layer itself coated with a surface semiconductor layer are disposed.

7. The device according to claim 6, wherein the substrate is of the semiconductor-on-insulator type and wherein the semiconductor support layer includes a charge trapping region, in particular a region rich in crystalline defects, such as a polysilicon layer.

8. The device according to claim 7, wherein the semiconductor support layer is a region rich in crystalline defects

9. The device according to claim 7, wherein the semiconductor support layer is a polysilicon layer.

10. The device according to claim 1, wherein the dielectric region is arranged on and in contact with said semiconductor region.

11. The device according to claim 1, wherein the first dielectric areas made of dielectric material with positive fixed charges and the dielectric areas made of dielectric material with negative fixed charges are in contact with each other.
